(19) United States
(12) Patent Application Publication
(10) Pub. No.: US 2026/0075699 A1
(43) Pub. Date: Mar. 12, 2026

(54) ELECTRONIC ASSEMBLY

(71) Applicants: INVENTEC (PUDONG) TECHNOLOGY CORPORATION, Shanghai (CN); INVENTEC CORPORATION, Taipei City (TW)

(72) Inventor: Jih Lung LIN, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/194,318

(22) Filed: Apr. 30, 2025

(30) Foreign Application Priority Data
Sep. 6, 2024 (CN) 202411252232.6

(51) Int. Cl. H05K 1/02; H05K 1/14; H05K 7/20

(52) U.S. Cl. CPC H05K 1/0203; H05K 1/144; H05K 7/20145; H05K 7/20154; H05K 7/20172; H05K 7/20409; H05K 2201/066

(57) ABSTRACT

An electronic assembly including a first circuit board assembly, a second circuit board assembly and a heat sink. The first circuit board assembly includes a first circuit board and a first heat source. The second circuit board assembly includes a second circuit board and a second heat source. The heat sink includes a base part, a plurality of fin parts and a thermally conductive cover part. The base part has a hole. The plurality of fin parts and the thermally conductive cover part protrude from a side of the base part. The thermally conductive cover part covers the hole to form at least one heat dissipation channel in fluid communication with the hole. The base part is thermally coupled to the second heat source, and two opposite sides of the thermally conductive cover part are thermally coupled to the base part and the first heat source, respectively.

### CROSS-REFERENCE TO RELATED APPLICATIONS

This non-provisional application claims priority under 35 U.S.C. § 119(a) on Patent Application No(s). 202411252232.6 filed in China, on Sep. 6, 2024, the entire contents of which are hereby incorporated by reference.

### BACKGROUND OF THE INVENTION

### Technical Field of the Invention

The invention relates to an electronic assembly, more particularly to an electronic assembly including heat source and heat sink.

### Description of the Related Art

In general, in order to enhance the space utilization, it is common for the electronic component to include an electronic assembly configured by two adjacent circuit board assemblies. In such electronic assembly, to effectively cool the two circuit board assemblies, each circuit board assembly is required to be cooled by an exclusive heat sink.

However, the heat sink has a complex structure and thus is required to be manufactured by a complex mold. Thus, cooling each circuit board assembly by exclusive heat sink (manufactured by exclusive mold) significantly increases the manufacture cost of the electronic assembly. That is, conventional electronic assembly is unable to effective cool the circuit board assemblies without significantly increasing the manufacture cost thereof.

### SUMMARY OF THE INVENTION

The invention provides an electronic assembly allowing the circuit board assemblies to be effective cooled without significantly increasing the manufacture cost thereof.

One embodiment of this invention provides an electronic assembly including a first circuit board assembly, a second circuit board assembly and a heat sink. The first circuit board assembly includes a first circuit board and a first heat source disposed on the first circuit board. The second circuit board assembly includes a second circuit board and a second heat source disposed on the second circuit board. The first circuit board and the second circuit board are spaced apart from each other. The heat sink is located between the first circuit board and the second circuit board and includes a base part, a plurality of fin parts and a thermally conductive cover part. The base part has a hole. The plurality of fin parts and the thermally conductive cover part protrude from a side of the base part. The thermally conductive cover part covers the hole to form at least one heat dissipation channel in fluid communication with the hole. The base part is thermally coupled to the second heat source, and two opposite sides of the thermally conductive cover part are thermally coupled to the base part and the first heat source, respectively.

According to the electronic assembly disclosed by above embodiments, the base part of the heat sink is thermally coupled to the second heat source, two opposite sides of the thermally conductive cover part respectively are thermally coupled to the base part of the heat sink and the first heat source, and the thermally conductive cover part forms at least one heat dissipation channel. With the aforementioned configuration of the thermally conductive cover part, the thermally conductive cover part not only acts as a medium for transferring heat between the first heat source and the heat sink, but also allows the cold air to flow through the heat dissipation channel without being blocked. Thus, the heat generated by the first heat source and the second heat source is allowed to be effectively absorbed by a single one heat sink including the thermally conductive cover part, thereby saving the cost for manufacturing multiple heat sinks having complex structures. Accordingly, the first circuit board assembly and the second circuit board assembly are allowed to be cooled efficiently without significantly increasing the manufacture cost of the electronic assembly.

Also, the base part has the hole in fluid communication with the heat dissipation channel. That is, the base part, the fin parts and the thermally conductive cover part of the heat sink are allowed to be integrally formed as a single piece by misalignment of the molds (i.e., shut off) during die casting. In this way, the cost for assembling the thermally conductive cover part to the base part is saved, thereby further reducing the manufacture cost of the electronic assembly.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a perspective view of an electronic assembly according to an embodiment of the invention;

FIG. 2 is a side cross-sectional view of the electronic assembly in FIG. 1 taken along line 2-2;

FIG. 3 is a perspective view of a heat sink of the electronic assembly in FIG. 1; and

FIG. 4 is a partially enlarged view of the electronic assembly in FIG. 2.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

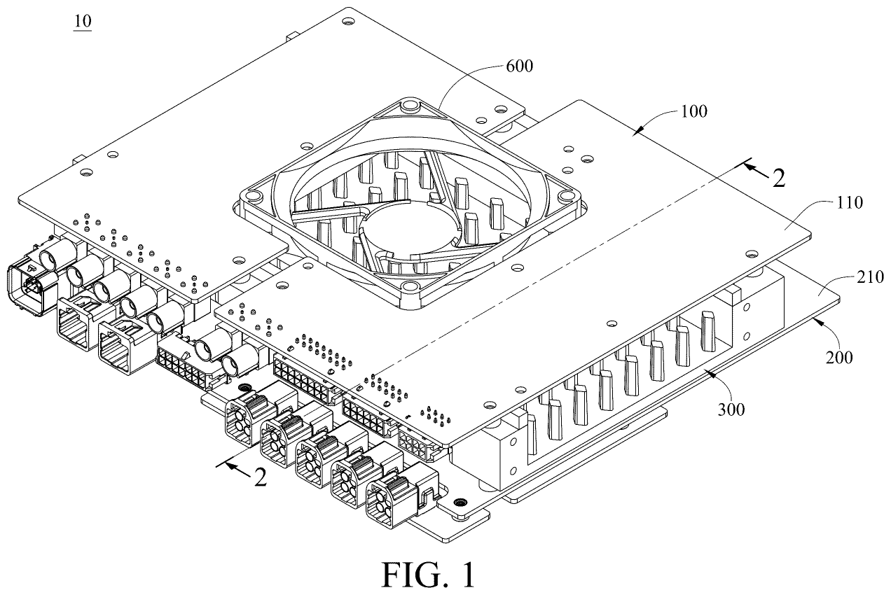

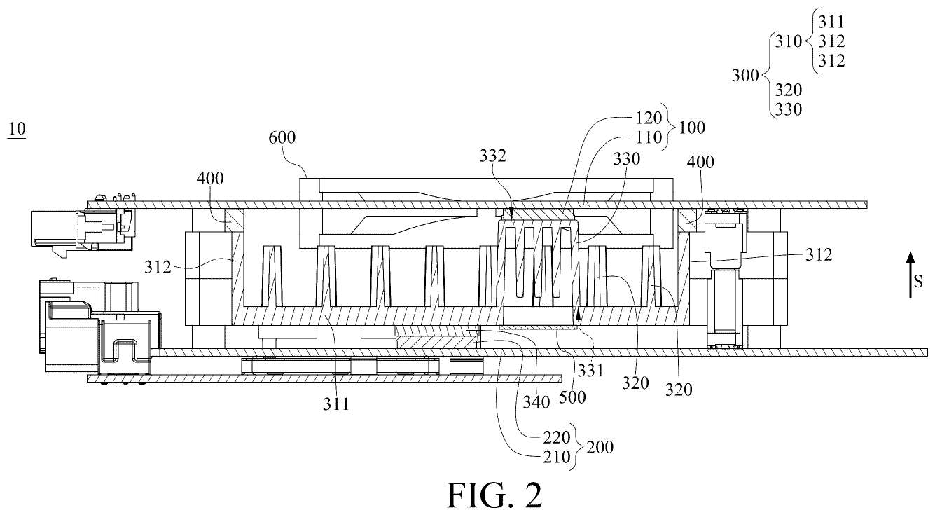

Please refer to FIGS. 1 and 2. FIG. 1 is a perspective view of an electronic assembly 10 according to an embodiment of the invention. FIG. 2 is a side cross-sectional view of the electronic assembly 10 in FIG. 1 taken along line 2-2. In this embodiment, the electronic assembly 10 includes, for example, a first circuit board assembly 100, a second circuit board assembly 200, a heat sink 300, two sealing pads 400, a blocking film 500 and a fan 600.

The first circuit board assembly 100 includes a first circuit board 110 and a first heat source 120 disposed thereon. The second circuit board assembly 200 includes a second circuit board 210 and a second heat source 220 disposed thereon. The first circuit board 110 and the second circuit board 210 are spaced apart from each other.

In addition, as shown in FIG. 2, the first heat source 120 and the second heat source 220 are misaligned with each other along, for example, a stacking direction S of the first circuit board 110 and the second circuit board 210.

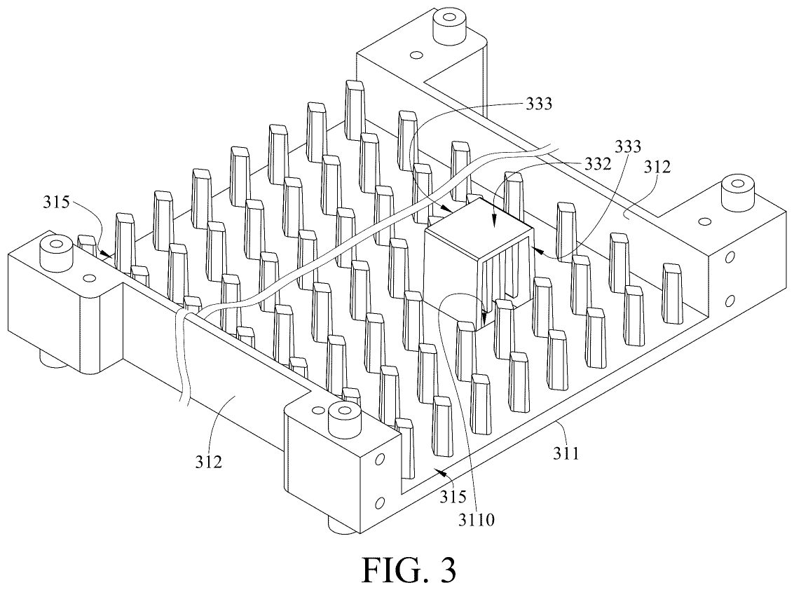

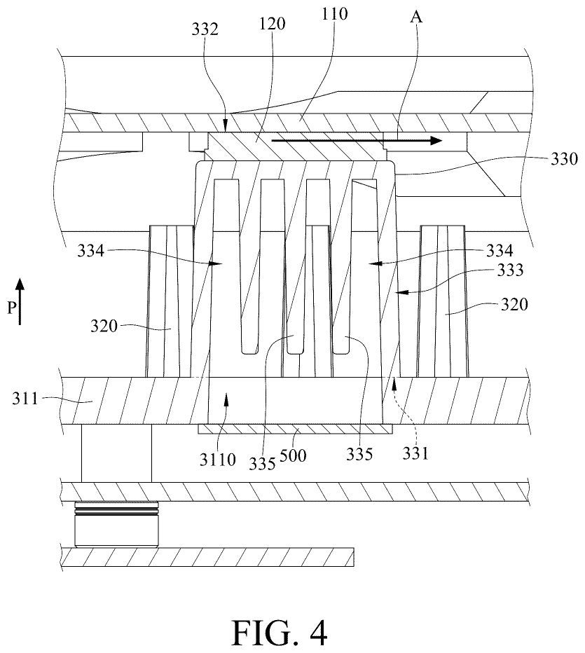

Please refer to FIGS. 2 to 4. FIG. 3 is a perspective view of the heat sink 300 of the electronic assembly 10 in FIG. 1. FIG. 4 is a partially enlarged view of the electronic assembly 10 in FIG. 2.

The heat sink 300 is located between the first circuit board 110 and the second circuit board 210, and includes a base part 310, a plurality of fin parts 320 and a thermally conductive cover part 330. The base part 310 includes a bottom plate 311 and two side plates 312. The two side plates 312 are respectively connected to two opposite sides of the bottom plate 311 so that the two side plates 312 and the bottom plate 311 together form two openings 315. The bottom plate 311 has a hole 3110. The fin parts 320 and the thermally conductive cover part 330 protrude from the same side of the bottom plate 311. A side of the bottom plate 311 located away from the fin parts 320 is thermally coupled to the second heat source 220 via, for example, a thermally conductive protrusion 340 and a thermally conductive pad (not shown).

The thermally conductive cover part 330 has a first coupling surface 331, a second coupling surface 332, two ventilation surfaces 333 and a plurality of heat dissipation channels 334. The first coupling surface 331 and the second coupling surface 332 face away from each other. The two ventilation surfaces 333 face away from each other and connect the first coupling surface 331 and the second coupling surface 332. In addition, the two ventilation surfaces 333 face toward the two openings 315, respectively. The thermally conductive cover part 330 covers the hole 3110 and forms the heat dissipation channels 334 in fluid communication with the hole 3110. The heat dissipation channels 334 penetrate through the two ventilation surfaces 333. The first coupling surface 331 and the second coupling surface 332 are thermally coupled to the bottom plate 311 and the first heat source 120, respectively. The second coupling surface 332 is thermally coupled to the first heat source 120 via, for example, a thermally conductive pad (not shown). The hole 3110 is located on a position where the first coupling surface 331 and the bottom plate 311 are connected. In this embodiment, the base part 310, the fin parts 320 and the thermally conductive cover part 330 are, for example, integrally formed as a single piece by misalignment of the molds (i.e., shut off) during die casting so that the bottom plate 311 has the hole 3110.

Moreover, in this embodiment, the thermally conductive cover part 330 further has a plurality of partitions 335. The partitions 335 define the heat dissipation channels 334 in fluid communication with the hole 3110. In other embodiments, there may be one heat dissipation channel. That is, in other embodiments, the thermally conductive cover part may not have the partitions.

Also, in this embodiment, as shown in FIG. 2, the two sealing pads 400 are respectively clamped between the two side plates 312 and the first circuit board 110 to enhance the air tightness between the heat sink 300 and the first circuit board 110. The two sealing pads 400 are, for example, foams. Note that in other embodiments, if the first heat source and the second heat source have low power, the electronic assembly may not include the sealing pads 400.

Furthermore, in this embodiment, as shown in FIG. 4, an arranging direction A of the heat dissipation channels 334 is, for example, perpendicular to a protruding direction P along which the fin parts 320 protrude from the bottom plate 311. Thus, a cold air is facilitated to flow to the fin parts 320 through the heat dissipation channels 334. That is, the cold air flowing to the fin parts 320 through the heat dissipation channels 334 is subjected to a small resistance. However, in other embodiments, if the first heat source and the second heat source have low power, the arranging direction of the heat dissipation channels may be parallel to the protruding direction along which the fin parts protrude from the bottom plate.

Additionally, in this embodiment, as shown in FIG. 4, the blocking film 500 is disposed on a side of the bottom plate 311 located away from the fin parts 320 and the thermally conductive cover part 330, and covers the hole 3110 so as to enhance the air tightness between the heat sink 300 and the first circuit board 110. The blocking film 500 is, for example, Mylar. Note that in other embodiments, if the first heat source and the second heat source have low power, the electronic assembly may not include the blocking film 500.

Please refer to FIGS. 1 and 2 again. The fan 600 and the first circuit board assembly 100 are located on the same side of the heat sink 300. The fan 600 is, for example, fixed to the base part 310 of the heat sink 300, and is configured to blow an airflow (not shown) flowing to the fin parts 320 through the heat dissipation channels 334. In other embodiments, the electronic assembly may not include the fan 600, and the airflow may be blown by a fan external to the electronic assembly.

According to the electronic assembly disclosed by above embodiments, the base part of the heat sink is thermally coupled to the second heat source, two opposite sides of the thermally conductive cover part respectively are thermally coupled to the base part of the heat sink and the first heat source, and the thermally conductive cover part forms at least one heat dissipation channel. With the aforementioned configuration of the thermally conductive cover part, the thermally conductive cover part not only acts as a medium for transferring heat between the first heat source and the heat sink, but also allows the cold air to flow through the heat dissipation channel without being blocked. Thus, the heat generated by the first heat source and the second heat source is allowed to be effectively absorbed by a single one heat sink including the thermally conductive cover part, thereby saving the cost for manufacturing multiple heat sinks having complex structures. Accordingly, the first circuit board assembly and the second circuit board assembly are allowed to be cooled efficiently without significantly increasing the manufacture cost of the electronic assembly.

Also, the base part has the hole in fluid communication with the heat dissipation channel. That is, the base part, the fin parts and the thermally conductive cover part of the heat sink are allowed to be integrally formed as a single piece by misalignment of the molds (i.e., shut off) during die casting. In this way, the cost for assembling the thermally conductive cover part to the base part is saved, thereby further reducing the manufacture cost of the electronic assembly.

In an embodiment of the invention, the electronic assembly of this invention may be applied in a server. The server may apply Artificial Intelligence (AI) computing, Edge Computing, or may be used as a 5G server, a cloud server or a Vehicle-to-everything (V2X) server.

In an embodiment of the invention, the electronic assembly of this invention may be applied in an automotive device, such as a carputer or a server of an In-Vehicle Infotainment (IVI), or may be applied in a 5G server, a cloud server or a Vehicle-to-everything (V2X) server.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. An electronic assembly, comprising:
a first circuit board assembly, comprising a first circuit board and a first heat source disposed on the first circuit board;
a second circuit board assembly, comprising a second circuit board and a second heat source disposed on the second circuit board, wherein the first circuit board and the second circuit board are spaced apart from each other; and
a heat sink, located between the first circuit board and the second circuit board and comprising a base part, a plurality of fin parts and a thermally conductive cover part, wherein the base part has a hole, the plurality of fin parts and the thermally conductive cover part protrude from a side of the base part, the thermally conductive cover part covers the hole to form at least one heat dissipation channel in fluid communication with the hole, the base part is thermally coupled to the second heat source, and two opposite sides of the thermally conductive cover part are thermally coupled to the base part and the first heat source, respectively.

2. The electronic assembly according to claim 1, wherein the base part, the plurality of fin parts and the thermally conductive cover part are integrally formed as a single piece.

3. The electronic assembly according to claim 1, wherein the first heat source and the second heat source are misaligned with each other along a stacking direction of the first circuit board and the second circuit board.

4. The electronic assembly according to claim 1, further comprising a blocking film, wherein the blocking film is disposed on a side of the base part located away from the plurality of fin parts and the thermally conductive cover part and covers the hole.

5. The electronic assembly according to claim 1, wherein the thermally conductive cover part has a first coupling surface, a second coupling surface, two ventilation surfaces and at least one heat dissipation channel, the first coupling surface and the second coupling surface face away from each other, the two ventilation surfaces face away from each other and connect the first coupling surface and the second coupling surface, the at least one heat dissipation channel penetrates through the two ventilation surfaces, the first coupling surface and the second coupling surface respectively are thermally coupled to the base part and the first heat source, and the hole is located on a position where the first coupling surface and the base part are connected.

6. The electronic assembly according to claim 5, wherein the thermally conductive cover part further has at least one partition, the at least one heat dissipation channel comprises a plurality of heat dissipation channels, and the at least one partition defines the plurality of heat dissipation channels in fluid communication with the hole.

7. The electronic assembly according to claim 6, wherein an arranging direction of the plurality of heat dissipation channels is perpendicular to a protruding direction along which the plurality of fin parts protrude from the base part.

8. The electronic assembly according to claim 5, wherein the base part comprises a bottom plate and two side plates, the two side plates are respectively connected to two opposite sides of the bottom plate so that the two side plates and the bottom plate together form two openings, the hole is located on the bottom plate, the plurality of fin parts and the thermally conductive cover part protrude from a side of the bottom plate, a side of the bottom plate located away from the plurality of fin parts is thermally coupled to the second heat source, and the two ventilation surfaces of the thermally conductive cover part face toward the two openings, respectively.

9. The electronic assembly according to claim 8, further comprising two sealing pads clamped between the two side plates and the first circuit board, respectively.

10. The electronic assembly according to claim 1, further comprising a fan, wherein the fan and the first circuit board assembly are located on a side of the heat sink, the fan is fixed to the base part of the heat sink, and is configured to blow an airflow flowing to the plurality of fin parts through the at least one heat dissipation channel.
